(19) United States
(12) Patent Application Publication
(10) Pub. No.: US 2024/0324189 A1
(43) Pub. Date: Sep. 26, 2024

(54) SEMICONDUCTOR MEMORY DEVICE

(71) Applicant: Samsung Electronics Co., Ltd., Suwon-si (KR)

(72) Inventor: Sena CHOI, Suwon-si (KR)

(73) Assignee: Samsung Electronics Co., Ltd., Suwon-si (KR)

(21) Appl. No.: 18/419,098

(22) Filed: Jan. 22, 2024

(30) Foreign Application Priority Data
Mar. 24, 2023 (KR) 10-2023-0039112
May 24, 2023 (KR) 10-2023-0067134

(51) Int. Cl. H10B 12/00

(52) U.S. Cl. CPC H10B 12/50; H10B 12/315

(57) ABSTRACT

A semiconductor memory device includes a substrate having a memory cell region and a dummy cell region surrounding the memory cell region, wherein a plurality of memory cells are arranged in the memory cell region, a plurality of first active regions each having a bar shape in the memory cell region, the plurality of first active regions separated from each other by a first gap in a first direction and extending in a second direction perpendicular to the first direction, and a plurality of second active regions on the plurality of first active regions, the plurality of second active regions each having a circular shape and separated from each other by a second gap in the second direction.

### CROSS-REFERENCE TO RELATED APPLICATIONS

This application is based on and claims priority under 35 U.S.C. § 119 to Korean Patent Application Nos. 10-2023-0039112, filed on Mar. 24, 2023 and 10-2023-0067134, filed on May 24, 2023, in the Korean Intellectual Property Office, the disclosures of which are incorporated by reference herein in their entirety.

### BACKGROUND

Various example embodiments relate to a semiconductor memory device. More particularly, example embodiments to a semiconductor memory device for securing or helping to secure a contact area by increasing an active region.

Semiconductor memory devices store information, such as data and/or program instructions. Semiconductor memory devices are largely classified into dynamic random access memory (DRAM) and static RAM (SRAM). Here, DRAM is a memory that reads stored information and stores other information. Information may be read from or written to DRAM, but information stored in DRAM is lost unless the information is rewritten to DRAM in a certain period of time while power is being supplied to DRAM. As such, DRAM needs to or is expected to be refreshed continuously, but DRAM is widely used as a large-capacity memory because the price per memory cell is low and/or the integration density of DRAM may be increased.

With the high integration density of semiconductor devices, the semiconductor chip size is decreasing, and accordingly, the size of semiconductor devices formed in a chip is also decreasing. In particular, the decrease in size of an active region and a gate affects processes of forming a semiconductor device, such as subsequent processes of forming a capacitor and a bit line. In particular, with the decrease in the area of a storage node and a bit line contact, which are formed in an active region between gates, it may be difficult to form a contact, and/or electrical characteristics of semiconductor memory devices may degrade.

### SUMMARY

Various example embodiments may provide a semiconductor memory device for effectively securing or helping to secure a contact area by increasing an active region.

Alternatively or additionally, various example embodiments may also provide a semiconductor memory device having improved mechanical stability and/or warpage of an active region.

Features of example embodiments are not limited to those mentioned above, and inventive concepts that have not been mentioned will be clearly understood by one of skill in the art from the description below.

According to some example embodiments, there is provided a semiconductor memory device including a substrate having a memory cell region and a dummy cell region surrounding the memory cell region, wherein a plurality of memory cells are arranged in the memory cell region, a plurality of first active regions each having a bar shape in the memory cell region, the plurality of first active regions being separated from each other by a first gap in a first direction and extending in a second direction perpendicular to the first direction, and a plurality of second active regions on the plurality of first active regions, the plurality of second active regions each having a circular shape and being separated from each other by a second gap in the second direction.

Alternatively or additionally according to various example embodiments, there is provided a semiconductor memory device including a substrate having a memory cell region and a dummy cell region surrounding the memory cell region, wherein a plurality of memory cells are arranged in the memory cell region, a plurality of first active regions each having a bar shape in the memory cell region, the plurality of first active regions separated from each other by a first gap in a first direction and extending in a second direction that is perpendicular to the first direction, and a plurality of second active regions on the plurality of first active regions, the plurality of second active regions each including a curve and separated from each other by a second gap in the second direction.

Alternatively or additionally according to some example embodiments, there is provided a semiconductor memory device including a substrate having a memory cell region, a peripheral region, and a dummy cell region between the memory cell region and the peripheral region, a plurality of first active regions each having a bar shape in the memory cell region, the plurality of first active regions separated from each other by a first gap in a first direction and extending in a second direction perpendicular to the first direction, a plurality of second active regions on the plurality of first active regions, the plurality of second active regions each including a curve and separated from each other by a second gap in the second direction, at least one logic active region in the peripheral region, a plurality of dummy active regions in the dummy cell region, an isolation structure defining the plurality of first active regions, the plurality of second active regions, the at least one logic active region, and the plurality of dummy active regions, a plurality of word lines extending across the plurality of first active regions, the plurality of second active regions, and the plurality of dummy active regions in the first direction and being parallel with each other, a plurality of bit lines extending in the second direction on the substrate and parallel with each other, a plurality of buried contacts on the substrate and filling a lower portion of a space between the plurality of bit lines, a plurality of landing pads filling an upper portion of the space between the plurality of bit lines and extending on the plurality of bit lines, and a plurality of memory structures respectively connected to the plurality of landing pads.

### BRIEF DESCRIPTION OF THE DRAWINGS

Embodiments will be more clearly understood from the following detailed description taken in conjunction with the accompanying drawings in which:

FIG. 1 is a schematic layout diagram of a semiconductor memory device according to some example embodiments;

FIG. 2A is a layout diagram illustrating word lines and active regions in FIG. 1;

FIG. 2B is a schematic layout diagram illustrating a part of an active region pattern after an insulating pattern is additionally formed in FIG. 2A;

FIG. 3 is a cross-sectional view taken along line A-A′ in FIG. 1;

FIG. 4 is a cross-sectional view taken along line B-B′ in FIG. 1;

FIG. 5A is a schematic layout diagram illustrating the pattern of an active region in a horizontal cross-section, according to some example embodiments;

FIG. 5B is a schematic layout diagram illustrating the pattern of an active region in a horizontal cross-section, according to some example embodiments;

FIG. 6A is a schematic layout diagram illustrating the pattern of an active region in a horizontal cross-section after an insulating pattern is formed by a trimming process in FIG. 5A, according to some example embodiments;

FIG. 6B is a schematic layout diagram illustrating the pattern of an active region in a horizontal cross-section after an insulating pattern is formed by a trimming process in FIG. 5B, according to some example embodiments; and

FIG. 7 is a layout diagram illustrating the arrangement relationship of the patterns of an active region in a horizontal cross-section, according to some example embodiments.

### DETAILED DESCRIPTION OF VARIOUS EXAMPLE EMBODIMENTS

Hereinafter, some example embodiments are described in detail with reference to the accompanying drawings. In the drawings, like numerals denote like elements and redundant descriptions thereof will be omitted.

As various embodiments allow for various changes and/or numerous embodiments, specific example embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed in example embodiments. In the description of various embodiments, certain detailed descriptions of the related art are omitted, for example when it is deemed that they may unnecessarily obscure the essence of inventive concepts.

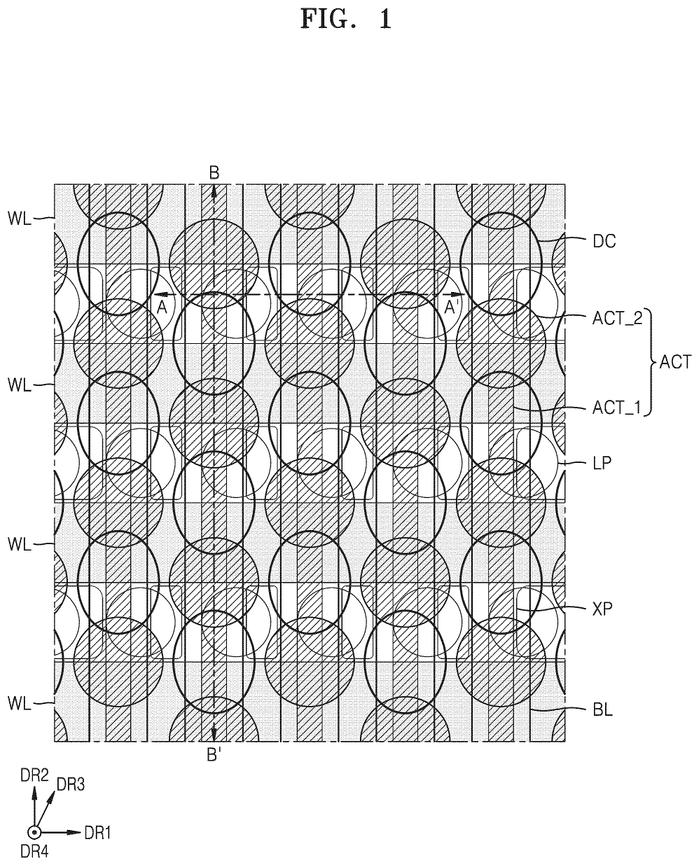

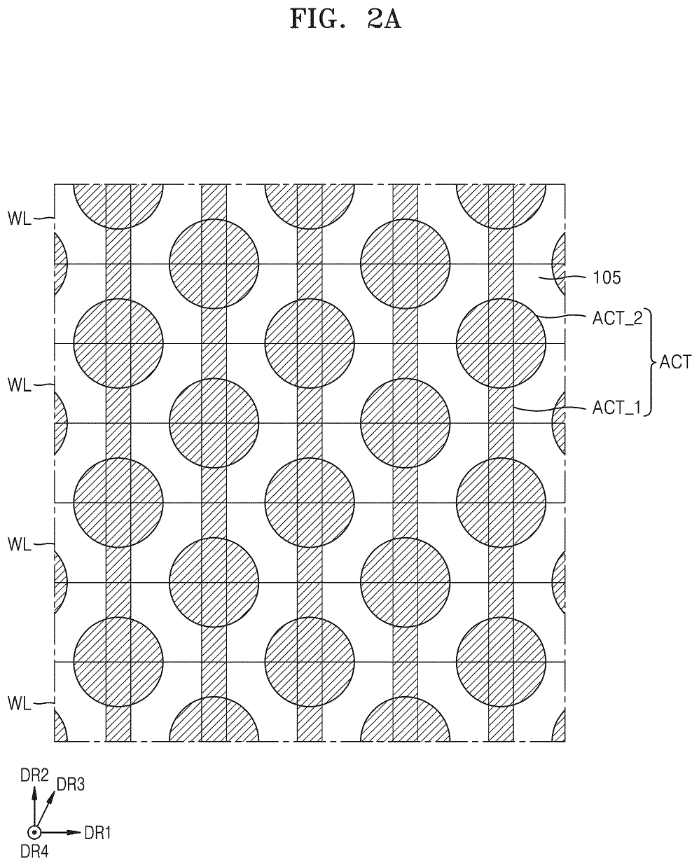

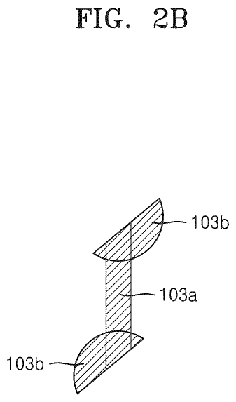

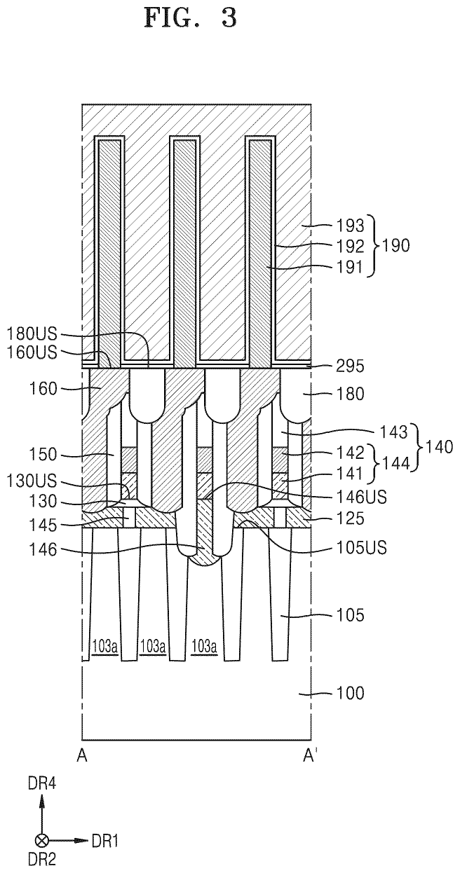

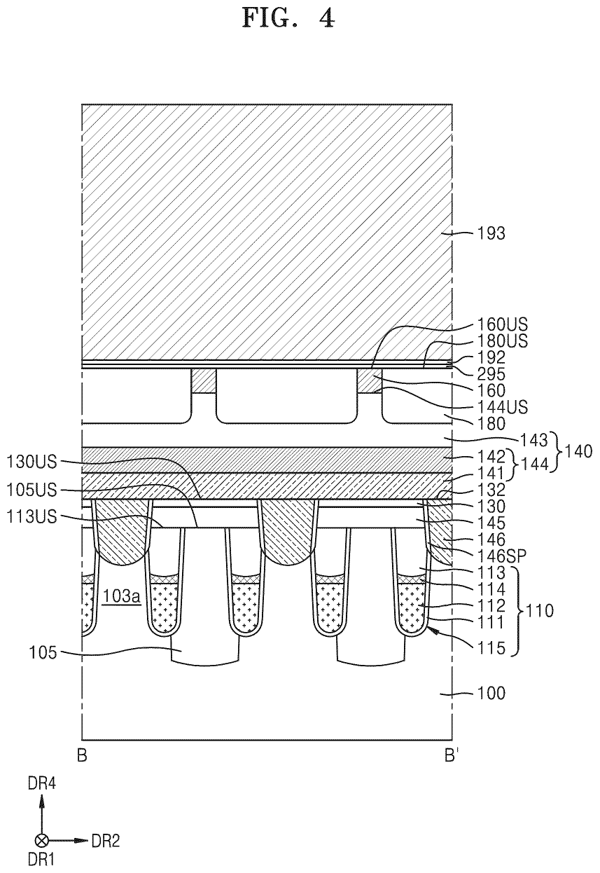

FIG. 1 is a schematic layout diagram of a semiconductor memory device according to some example embodiments. FIG. 2A is a layout diagram illustrating word lines and active regions in FIG. 1. FIG. 2B is a schematic layout diagram illustrating a part of an active region pattern after an insulating pattern is additionally formed in FIG. 2A. FIG. 3 is a cross-sectional view taken along line A-A′ in FIG. 1. FIG. 4 is a cross-sectional view taken along line B-B′ in FIG. 1.

Referring to FIGS. 1 and 2A, a semiconductor memory device according to some example embodiments may include a plurality of active regions ACT.

An active region ACT may be defined by a cell isolation film 105 in a substrate 100 (refer to FIG. 3). With the decrease in the design rules of the semiconductor memory device, a cell active region may have a linear bar shape. For example, the active region ACT may extend in a second direction DR2.

A plurality of gate electrodes may extend across the active region ACT in a first direction DR1. The gate electrodes may be parallel with each other. For example, the gate electrodes may correspond to rows or word lines WL. The word lines WL may be arranged at regular intervals. A width of each of the word lines WL and/or a gap between two adjacent word lines WL and/or a pitch of the word lines WL may be determined, e.g., according to design rules.

Referring to FIG. 2B, an insulating pattern may be formed in a diagonal direction by performing a trimming process, for example on portions of FIG. 2A. Through this process, an active region may be physically separated into parts and thus have an asymmetric pattern.

According to example embodiments of FIG. 2B, each active region ACT may be divided into three portions. The active region ACT may include a storage connection region 103b and a bit line connection region 103a. The bit line connection region 103a may be in the middle of the active region ACT and the storage connection region 103b may be at an end of the active region ACT.

According to example embodiments in FIG. 2B, the active region ACT may be divided into two categories according to a shape thereof. The bit line connection region 103a in the middle of the active region ACT may have a straight line shape and may correspond to a part of a first active region ACT_1 in FIG. 2A. The storage connection region 103b at each of opposite ends of the active region ACT may have a curve, e.g., a circular curve and/or a semicircular curve, and may correspond to a part of a second active region ACT_2 in FIG. 2A. The first active region ACT_1 (in FIG. 2A) and the second active region ACT_2 (in FIG. 2A) may integrally form an active region island.

For example, the bit line connection region 103a may be connected to a bit line BL and the storage connection region 103b may be connected to a memory unit, such as a capacitor or a data storage 190 (in FIG. 3). For example, the bit line connection region 103a may correspond to a common drain region and the storage connection region 103b may correspond to a source region. Each of the word lines WL and the bit line connection region 103a and the storage connection region 103b, which are adjacent to each word line WL, may form or correspond to a transistor.

A plurality of columns or bit lines BL may be on the word line WL and may extend in the second direction DR2 that is perpendicular to the word line WL. The bit lines BL may be parallel with each other. The bit lines BL may be arranged at regular intervals. The width of each of the bit lines BL and/or the gap between two adjacent bit lines BL and/or the pitch of the adjacent bit lines BL may be determined according to the design rules. The number of bit lines BL may be the same as, greater than, or less than the number of word lines WL.

A fourth direction DR4 may be orthogonal to the first direction DR1, the second direction DR2, and a third direction DR3, which may be an arbitrary direction. The fourth direction DR4 may correspond to the thickness direction of the substrate 100.

According to some example embodiments, a semiconductor memory device may include various contact arrays on the active region ACT. For example, the contact arrays may include a bit line contact DC, a node pad XP, and a landing pad LP.

Here, the bit line contact DC may electrically connect the active region ACT to a bit line BL. The node pad XP may correspond to a connection pad that connects the active region ACT to a lower electrode 191 (in FIG. 3) of a capacitor. Due to the arrangement structure, the contact area between the node pad XP and the active region ACT may be small. Accordingly, a conductive landing pad LP may be introduced to expand the contact area with the active region ACT and the contact area with the lower electrode 191 of a capacitor.

The landing pad LP may be between the node pad XP and the lower electrode 191 (in FIG. 3) of a memory unit such as a capacitor and/or a memristor. The contact resistance between the active region ACT and the lower electrode 191 of a the memory unit may be decreased by expanding the contact area through the introduction of the landing pad LP.

The bit line contact DC may be connected to the bit line connection region 103a. The node pad XP may be connected to the storage connection region 103b.

Because the node pad XP is at each of opposite ends of the active region ACT, the landing pad LP may be adjacent to each of the opposite ends of the active region ACT and may overlap with at least a portion of the node pad XP. For example, the node pad XP may overlap with or at least partly overlap with the active region ACT and the cell isolation film 105 (in FIG. 4), which are between two adjacent word lines WL and between two adjacent bit lines BL.

Each of the word lines WL may be buried in the substrate 100. Each word line WL may cross the active region ACT between bit line contacts DC and/or between node pads XP.

Bit line contacts DC and node pads XP may be symmetrically arranged. Accordingly, the direct contacts DC and the node pads XP may be arranged in lines in the first direction DR1 and the second direction DR2. Landing pads LP may respectively overlap with the same sides of the bit lines BL in the first direction DR1, in which the word lines WL extend.

Referring to FIGS. 1 to 4, a semiconductor memory device according to some example embodiments may include a plurality of cell gate structures 110, a plurality of bit line structures 140, a plurality of node connection pads 125, a plurality of bit line contacts 146, and a data storage 190.

The substrate 100 may include a silicon substrate and/or a silicon-on-insulator (SOI). Alternatively or additionally, the substrate 100 may include, but is not limited to, silicon germanium, silicon germanium on insulator (SGOI), indium antimonide, lead telluride, indium arsenide, indium phosphide, gallium arsenide, or gallium antimonide.

The cell isolation film 105 may be in the substrate 100. The cell isolation film 105 may have a shallow trench isolation (STI) structure having an good or excellent device isolation characteristic. The cell isolation film 105 may define an active region ACT in a memory cell region.

The active region ACT defined by the cell isolation film 105 may have an asymmetric island shape including a straight line and a curve, as shown in FIGS. 1 to 2B. The active region ACT may have a form, in which asymmetric patterns physically divided by a diagonal line having an angle of less than 90 degrees with respect to a word line WL in the cell isolation film 105 are repeated. A portion having a curve in the active region ACT may have an arc shape.

For example, the cell isolation film 105 may include, but is not limited to, at least one selected from the group consisting of or including a silicon oxide film, a silicon nitride film, and a silicon oxynitride film.

Although it is illustrated that the cell isolation film 105 is constituted of a single insulating film, this is just for convenience of description and embodiments are not limited thereto. According to the distance between two adjacent active regions ACT, the cell isolation film 105 may be constituted of a single insulating film or multiple insulating films.

Although it is illustrated in FIG. 3 that a top surface 105US of the cell isolation film 105 is coplanar with the top surface of the substrate 100, it is just for convenience of description and embodiments are not limited thereto.

The cell gate structures 110 may be formed in the substrate 100 and the cell isolation film 105. The cell gate structures 110 may cross the cell isolation film 105 and the active regions ACT defined by the cell isolation film 105.

Each of the cell gate structures 110 may include a cell gate trench 115, a cell gate insulating film 111, a cell gate electrode 112, a cell gate capping pattern 113, and a cell gate capping conductive film 114.

Here, the cell gate electrode 112 may correspond to a word line. For example, the cell gate electrode 112 may correspond to a word line WL in FIG. 1. Unlike FIG. 4, each of the cell gate structures 110 may not include the cell gate capping conductive film 114.

Although not shown, the cell gate trench 115 may be relatively deep in the cell isolation film 105 and relatively shallow in the active regions ACT. The bottom surface of the word line WL may be curved. For example, the depth of the cell gate trench 115 in the cell isolation film 105 may be greater than the depth of the cell gate trench 115 in the active regions ACT.

The cell gate insulating film 111 may extend along the sidewall and bottom surface of the cell gate trench 115. The cell gate insulating film 111 may extend along the profile of at least a portion of the cell gate trench 115.

For example, the cell gate insulating film 111 may include at least one selected from the group consisting of or including silicon oxide, silicon nitride, silicon oxynitride, and a high-k dielectric material having a higher dielectric constant than the silicon oxide. For example, the high-k dielectric material may include at least one selected from the group consisting of or including boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The cell gate electrode 112 may be on the cell gate insulating film 111. The cell gate electrode 112 may fill a portion of the cell gate trench 115. The cell gate capping conductive film 114 may extend along the top surface of the cell gate electrode 112.

The cell gate electrode 112 may include at least one selected from the group consisting of or including metal, a metal alloy, conductive metal nitride, conductive metal carbide, metal silicide, a doped semiconductor material, conductive metal oxynitride, and conductive metal oxide. For example, the cell gate electrode 112 may include, but is not limited to, at least one selected from the group consisting of or including TiN, TaC, TaN, TiSiN, TaSiN, TaTiN, TiAlN, TaAlN, WN, Ru, TiAl, TiAlC—N, TiAlC, TiC, TaCN, W, Al, Cu, CoN, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and a combination thereof.

For example, the cell gate capping conductive film 114 may include, but is not limited to, polysilicon such as doped or undoped polysilicon, poly silicon germanium, amorphous silicon, or amorphous silicon germanium.

The cell gate capping pattern 113 may be on the cell gate electrode 112 and cell gate capping conductive film 114. The cell gate capping pattern 113 may fill a portion of the cell gate trench 115, which remains after the cell gate electrode 112 and the cell gate capping conductive film 114 are formed in the cell gate trench 115. Although it is illustrated that the cell gate insulating film 111 extends along the sidewall of the cell gate capping pattern 113, embodiments are not limited thereto.

For example, the cell gate capping pattern 113 may include at least one selected from the group consisting of or including silicon nitride (SiN), silicon oxynitride (SiON), silicon oxide (SiO₂), silicon carbonitride (SiCN), silicon oxycarbonitride (SiOCN), and a combination thereof.

It is illustrated that a top surface 113US of the cell gate capping pattern 113 is coplanar with the top surface 105US of the cell isolation film 105, but example embodiments are not limited thereto.

Although not shown, an impurity-doped region may be formed in at least one side of the cell gate structures 110. The impurity-doped region may correspond to a source/drain region of a transistor. The impurity-doped region may be formed in each of the bit line connection region 103a and the storage connection region 103b in FIG. 2B.

When a transistor including a word line WL and the bit line connection region 103a and the storage connection region 103b, which are adjacent to the word line WL, is an n-channel metal-oxide semiconductor (NMOS) transistor, the storage connection region 103b and the bit line connection region 103a may include a doped n-type impurity including at least one selected from the group consisting of or including phosphorus (P), arsenic (As), antimony (Sb), and bismuth (Bi). When a transistor including a word line WL and the bit line connection region 103a and the storage connection region 103b, which are adjacent to the word line WL, is a p-channel metal-oxide semiconductor (PMOS) transistor, the storage connection region 103b and the bit line connection region 103a may include a doped p-type impurity, e.g., boron (B). In some example embodiments, the transistor may include both n-type impurities at a first concentration and p-type impurities at a second concentration. The first concentration may be greater than (e.g., much greater than) the second concentration; alternatively, the first concentration may be less than (e.g., much less than) the second concentration.

Each of the bit line structures 140 may include a cell conductive line 144 and a cell line capping film 143. The cell conductive line 144 may be arranged on the substrate 100 and the cell isolation film 105, in which the cell gate structures 110 have been formed. The cell conductive line 144 may cross the cell isolation film 105 and the active regions ACT defined by the cell isolation film 105. The cell conductive line 144 may also cross the cell gate structures 110. Here, the cell conductive line 144 may correspond to a bit line. For example, the cell conductive line 144 may correspond to a bit line BL in FIG. 1.

The cell conductive line 144 may include a first cell conductive film 141 and a second cell conductive film 142. For example, the first cell conductive film 141 and the second cell conductive film 142 may include at least one selected from the group consisting of or including an impurity-doped semiconductor material, a conductive silicide compound, a conductive metal nitride, a two-dimensional (2D) material, a metal, and a metal alloy. In a semiconductor memory device according to some example embodiments, the 2D material may include a 2D allotrope and a 2D compound. For example, the 2D material may include, but is not limited to, at least one selected from the group consisting of or including graphene, molybdenum disulfide (MoS₂), molybdenum diselenide (MoSe₂), tungsten diselenide (WSe₂), and tungsten disulfide (WS₂). In other words, the 2D materials mentioned above are just examples, and 2D materials that may be included in a semiconductor memory device of the inventive concept are not limited to those described above.

For example, each of the first cell conductive film 141 and the second cell conductive film 142 may include, but is not limited to, polysilicon, Ti, TiSiN, tungsten, tungsten silicide, or a combination thereof. For example, the first cell conductive film 141 may include TiSiN and the second cell conductive film 142 may include tungsten.

The cell line capping film 143 may be on the cell conductive line 144. The cell line capping film 143 may extend in the second direction DR2 along the top surface of the cell conductive line 144. For example, the cell line capping film 143 may include at least one selected from the group consisting of or including silicon nitride, silicon oxynitride, silicon carbonitride, and silicon oxycarbonitride.

In a semiconductor memory device according to some example embodiments, the cell line capping film 143 may include a silicon nitride film. It is illustrated that the cell line capping film 143 is constituted of a single film, but embodiments are not limited thereto.

A bit line contact 146 may be between the cell conductive line 144 and the substrate 100. The cell conductive line 144 may be on the bit line contact 146.

The bit line contact 146 may be between the bit line connection region 103a of an active region ACT and the cell conductive line 144. The bit line contact 146 may be between cell gate electrodes 112 adjacent to each other in the second direction DR2. The bit line contact 146 may be directly connected to the bit line connection region 103a.

According to a plan view, the bit line contact 146 may have a circular shape or an oval shape. The planar area of the bit line contact 146 may be greater than the overlapping area between the bit line connection region 103a and the cell conductive line 144. The planar area of the bit line contact 146 may be greater than the planar area of the bit line connection region 103a.

The bit line contact 146 may electrically connect the cell conductive line 144 to the substrate 100. Here, the bit line contact 146 may include, for example, an impurity-doped semiconductor material.

The node connection pads 125 may be on the substrate 100. Each of the node connection pads 125 may be on the storage connection region 103b of the active region ACT. Each node connection pad 125 may be connected to the storage connection region 103b.

The node connection pad 125 may be between cell conductive lines 144 adjacent to each other in the first direction DR1. Although not shown, the node connection pad 125 may be between cell gate electrodes 112 adjacent to each other in the second direction DR2.

Based on the top surface 105US of the cell isolation film 105, a top surface of the node connection pad 125 may be lower than a top surface 146US of the bit line contact 146. Based on the top surface 105US of the cell isolation film 105, the top surface of the node connection pad 125 may be lower than the bottom surface of the cell conductive line 144.

The node connection pad 125 may electrically connect the data storage 190 to the substrate 100. Here, the node connection pad 125 may correspond to a node pad XP. For example, the node connection pad 125 may include at least one selected from the group consisting of or including an impurity-doped semiconductor material, a conductive silicide compound, conductive metal nitride, metal, and a metal alloy.

An upper cell insulating film 130 may separate node connection pads 125 from each other in the first direction DR1. Although not shown, the upper cell insulating film 130 may also separate node connection pads 125 from each other in the second direction DR2. The upper cell insulating film 130 may be on a pad separation pattern 145.

When a node connection pad 125 includes a first node connection pad and a second node connection pad, which are separated from each other in the first direction DR1, the pad separation pattern 145 may separate the first node connection pad from the second node connection pad in the first direction DR1. Although not shown, the pad separation pattern 145 may separate node connection pads 125 from each other in the second direction DR2.

When a node connection pad 125 includes a first node connection pad and a second node connection pad, which are separated from each other in the first direction DR1, the upper cell insulating film 130 may cover the top surface of the first node connection pad and the top surface of the second node connection pad.

A top surface 130US of the upper cell insulating film 130 may be coplanar with the top surface 146US of the bit line contact 146. For example, based on the top surface 105US of the cell isolation film 105, the height of the top surface 130US of the upper cell insulating film 130 may be the same as the height of the top surface 146US of the bit line contact 146.

The pad separation pattern 145 and the upper cell insulating film 130 may be between bit line contacts 146 adjacent to each other in the second direction DR2. The cell conductive line 144 may be on the top surface 130US of the upper cell insulating film 130. The top surface 130US of the upper cell insulating film 130 may be coplanar with the bottom surface of the cell conductive line 144.

In FIG. 4, a bit line contact spacer 146SP may be between the bit line contact 146 and the pad separation pattern 145. The bit line contact spacer 146SP may be arranged along a sidewall of the bit line contact 146. The bit line contact spacer 146SP on the sidewall of the bit line contact 146 may be separated from another bit line contact spacer 146SP in the second direction DR2.

For example, the bit line contact spacer 146SP may include at least one selected from the group consisting of or including silicon nitride (SiN), silicon oxynitride (SiON), silicon oxide (SiO₂), silicon carbonitride (SiCN), silicon oxycarbonitride (SiOCN), and a combination thereof. The upper cell insulating film 130 may be constituted of a single film, as shown in the drawings, but is not limited thereto. For example, the upper cell insulating film 130 may be constituted of a double film including a silicon oxide film and a silicon nitride film.

A bit line spacer 150 may be on respective sidewalls of the cell conductive line 144 and the cell line capping film 143.

With respect to a portion of the cell conductive line 144 on the bit line contact 146, the bit line spacer 150 may be on a sidewall of the cell conductive line 144, a sidewall of the cell line capping film 143, and a sidewall of the bit line contact 146. In FIG. 3, the bit line spacer 150 may be on a sidewall of the cell conductive line 144, a sidewall of the cell line capping film 143, and a sidewall of an upper portion of the bit line contact 146.

With respect to the remaining portion of the cell conductive line 144 not having the bit line contact 146 therebelow, the bit line spacer 150 may be on the upper cell insulating film 130.

Although it is illustrated that the bit line spacer 150 is constituted of a single film, this is just for convenience of description, and embodiments are not limited thereto. In other words, the bit line spacer 150 may have a multi-film structure. For example, the bit line spacer 150 may include, but is not limited to, a silicon oxide film, a silicon nitride film, a silicon oxynitride (SiON) film, a silicon oxycarbonitride (SiOCN) film, air, or a combination thereof.

A storage pad 160 may be on each of the node connection pads 125. The storage pad 160 may be electrically connected to each node connection pad 125. The storage pad 160 may be connected to the storage connection region 103b of the active region ACT. Here, the storage pad 160 may correspond to a landing pad LP.

In a semiconductor memory device according to some example embodiments, the storage pad 160 may extend to be connected to the node connection pad 125. The storage pad 160 may overlap with a portion of the top surface of each bit line structure 140.

For example, the storage pad 160 may include at least one selected from the group consisting of an impurity-doped semiconductor material, a conductive silicide compound, conductive metal nitride, conductive metal carbide, metal, and a metal alloy.

A pad separation insulating film 180 may be on the storage pad 160 and the bit line structure 140. For example, the pad separation insulating film 180 may be on the cell line capping film 143. The pad separation insulating film 180 may define storage pads 160 respectively forming a plurality of isolated regions.

The pad separation insulating film 180 may not cover a top surface 160US of the storage pad 160. The pad separation insulating film 180 may fill a pad separation recess. The pad separation recess may separate two adjacent storage pads 160 from each other. For example, the top surface 160US of the storage pad 160 may be coplanar with a top surface 180US of the pad separation insulating film 180.

The pad separation insulating film 180 may include an insulating material and may electrically separate a plurality of storage pads 160 from each other. For example, the pad separation insulating film 180 may include, but is not limited to, at least one selected from the group consisting of a silicon oxide film, a silicon nitride film, a silicon oxynitride film, a silicon oxycarbonitride film, and a silicon carbonitride film.

An etch stop film 295 may be on the storage pad 160 and the pad separation insulating film 180. The etch stop film 295 may include at least one selected from the group consisting of or including a silicon nitride film, a silicon carbonitride film, a silicon boron nitride (SiBN) film, a silicon oxynitride film, and a silicon oxycarbide film.

The data storage 190 may be on the storage pad 160. The data storage 190 may be electrically connected to the storage pad 160. A portion of the data storage 190 may be in the etch stop film 295.

For example, the data storage 190 may include, but is not limited to, a capacitor. The data storage 190 may include a lower electrode 191, a capacitor dielectric film 192, and an upper electrode 193. For example, the upper electrode 193 may include a plate upper electrode having a plate shape.

The lower electrode 191 may be on the storage pad 160. Although it is illustrated that the lower electrode 191 has a pillar shape, example embodiments are not limited thereto. The lower electrode 191 may have a cylindrical shape or a tapered shape.

The capacitor dielectric film 192 may be on the lower electrode 191. The capacitor dielectric film 192 may have formed along the profile of the lower electrode 191. The upper electrode 193 may be on the capacitor dielectric film 192. The upper electrode 193 may surround the outer wall of the lower electrode 191. Although it is illustrated that the upper electrode 193 is constituted of a single film, it is just for convenience of description, and example embodiments are not limited thereto.

For example, each of the lower electrode 191 and the upper electrode 193 may include, but is not limited to, a doped semiconductor material, conductive metal nitride (e.g., titanium nitride, tantalum nitride, niobium nitride, or tungsten nitride), metal (e.g., ruthenium, iridium, titanium, or tantalum), or conductive metal oxide (e.g., iridium oxide or niobium oxide).

For example, the capacitor dielectric film 192 may include, but is not limited to, silicon oxide, silicon nitride, silicon oxynitride, a high-k dielectric material, or a combination thereof.

In a semiconductor memory device according to some example embodiments, the capacitor dielectric film 192 may include a stack structure, in which zirconium oxide, aluminum oxide, and zirconium oxide are sequentially stacked. In a semiconductor memory device according to some example embodiments, the capacitor dielectric film 192 may include a dielectric film including hafnium (Hf). In a semiconductor memory device according to some example embodiments, the capacitor dielectric film 192 may have a stack structure of a ferroelectric material film and a paraelectric material film.

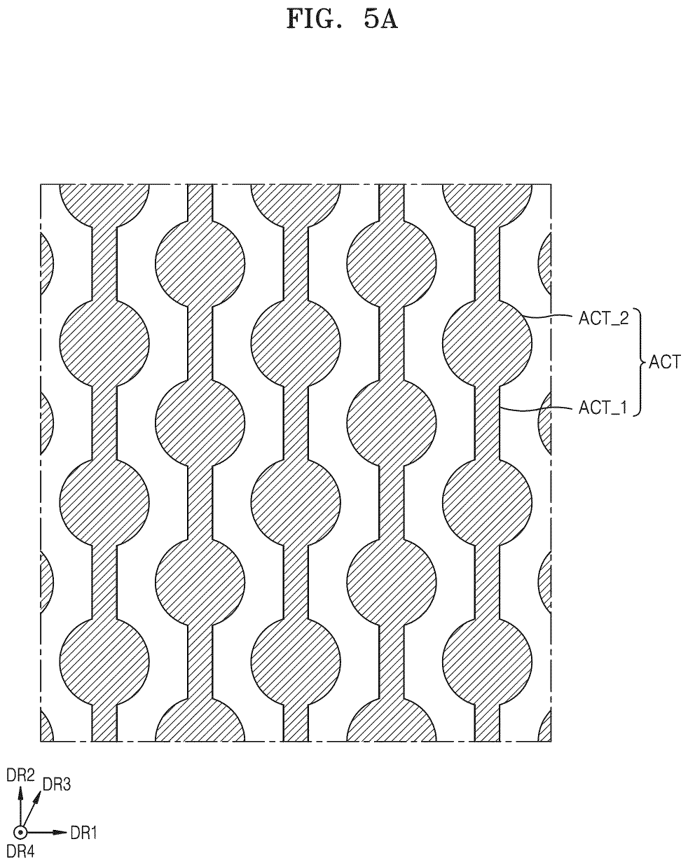

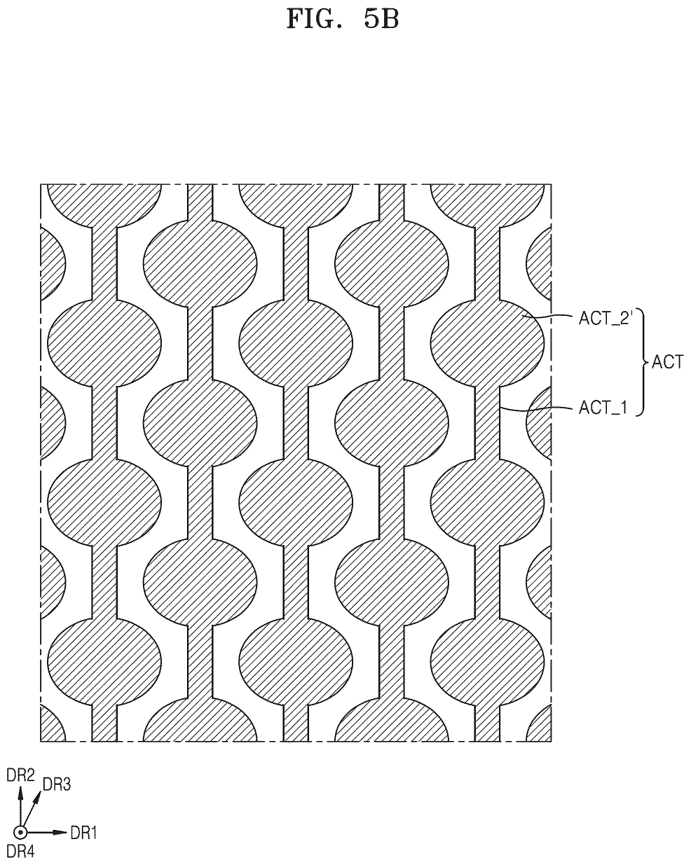

FIGS. 5A and 5B are schematic layout diagrams illustrating the patterns of an active region ACT in a horizontal cross-section according to embodiments.

Referring to FIGS. 5A and 5B, an island of an active region ACT may correspond to a combination of a first active region ACT_1 having a straight line shape and a second active region ACT_2 (in FIG. 5A) or ACT_2′ (in FIG. 5B) having a curved shape. Although it is illustrated in FIG. 5A that the pattern of the second active region ACT_2 has a circular shape, the inventive concept is not limited to FIG. 5A. For example, as shown in FIG. 5B, the pattern of the second active region ACT_2′ may have an oval shape having a long axis that is parallel with the first direction DR1. Unlike those illustrated in FIGS. 5A and 5B, a second active region is not limited to a circular shape or an oval shape but has any shape including a curve. The top surface of the second active region ACT_2 may be coplanar with the top surface of the first active region ACT_1.

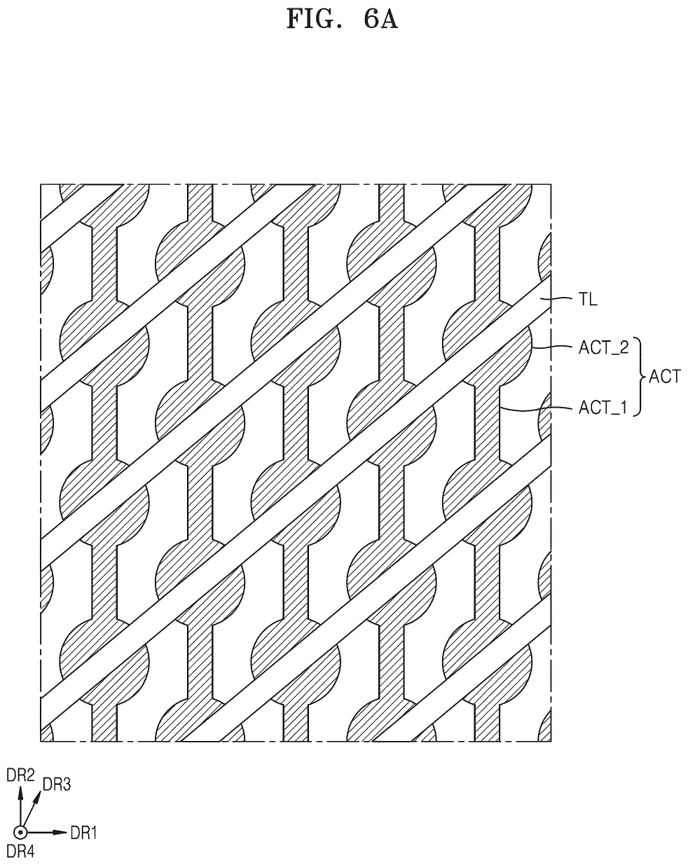

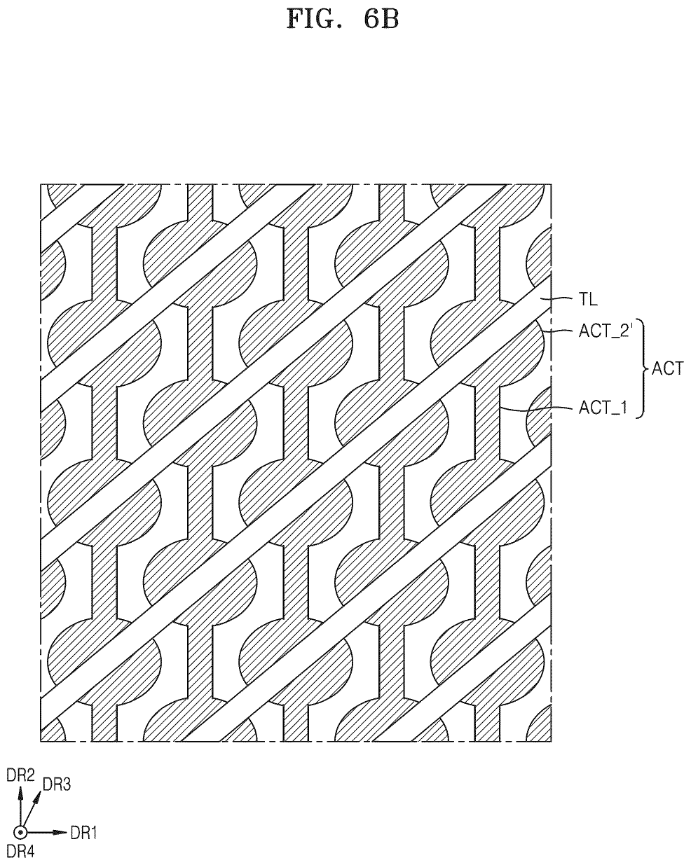

FIG. 6A is a schematic layout diagram illustrating the pattern of an active region ACT in a horizontal cross-section after an insulating pattern TL is formed by a trimming process in FIG. 5A, according to some example embodiments. FIG. 6B is a schematic layout diagram illustrating the pattern of an active region ACT in a horizontal cross-section after an insulating pattern TL is formed by a trimming process in FIG. 5B, according to some example embodiments. An insulating pattern TL may correspond to a trim line. According to various example embodiments, after the first active region ACT_1 is formed, the second active region ACT_2 may be formed. According to embodiments, after the second active region ACT_2 is formed, the first active region ACT_1 may be formed. The insulating pattern TL may be formed by a trimming process after both the first active region ACT_1 and the second active region ACT_2 are formed.

Referring to FIGS. 6A and 6B, by forming the insulating pattern TL through a trimming process, the patterns of the active region ACT may be physically separated from each other in a structure in which an asymmetric pattern (see FIG. 2B) is repeated. Insulating patterns TL may be formed at regular intervals in a certain direction. Here, the certain direction may form an acute angle with the first direction DR1 and the second direction DR2. When the insulating patterns TL are formed, the usable area of the active region ACT may increase, and accordingly, a contact area may be secured or may be more likely to be secured. Due to the asymmetric structure, the mechanical stability of the active region ACT may increase, and accordingly, the warpage of the active region ACT may be improved.

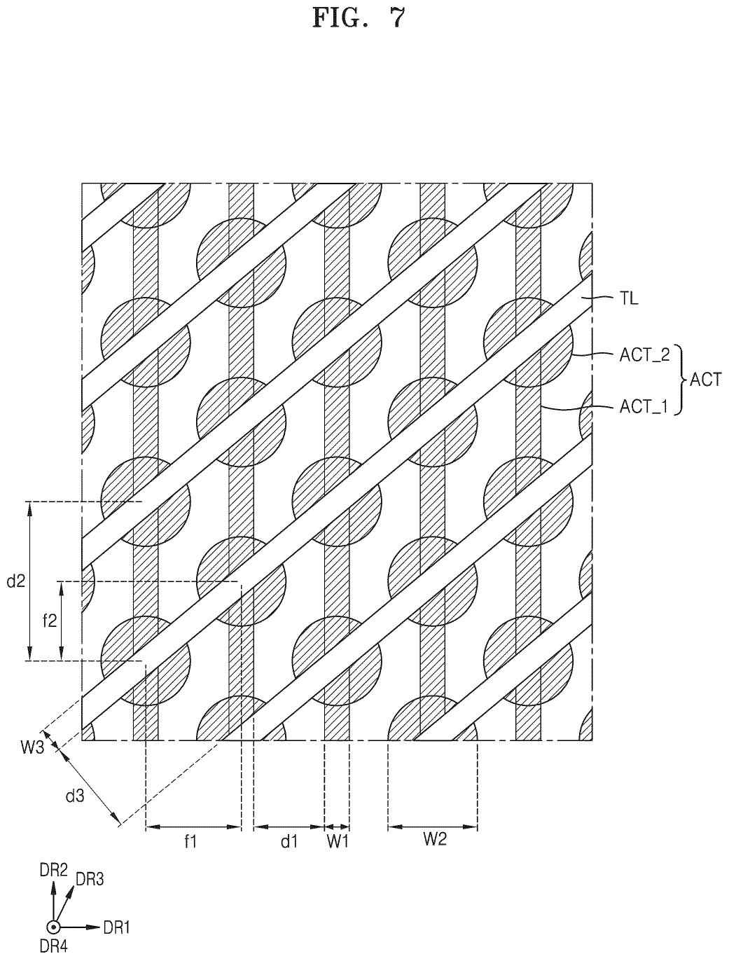

FIG. 7 is a layout diagram illustrating the arrangement relationship of the patterns of an active region ACT in a horizontal cross-section, according to some example embodiments.

Referring to FIG. 7, the patterns of the first active region ACT_1 may have a first width W1 in the first direction DR1 and may be separated from each other by a first gap d1 in the first direction DR1. The patterns of the second active region ACT_2 may be respectively on the patterns of the first active region ACT_1, which have a bar shape, and may be separated from each other by a second gap d2 in the second direction DR2. Here, the second gap d2 may be between the center of one of two adjacent patterns of the second active region ACT_2 and the center of the other pattern of the second active region ACT_2. A second width W2 of the second active region ACT_2 may correspond to the longest distance in one pattern of the second active region ACT_2. For example, when the pattern of the second active region ACT_2 is a circle, the second width W2 of the second active region ACT_2 may correspond to the diameter of the circle. For example, when the pattern of the second active region ACT_2 is an oval having the long axis that is parallel with the first direction DR1, the second width W2 of the second active region ACT_2 may correspond to the length of the long axis of the oval.

An insulating pattern TL may be formed obliquely on a substrate to make an angle less than 90 degrees with respect to the first direction D1 and the second direction D2 and may have a third width W3. Two adjacent insulating patterns TL may be separated from each other by a third gap d3. In some example embodiments, each of the insulating patterns TL may pass through the respective centers of the patterns of the second active region ACT_2.

In some example embodiments, the second width W2 may be less than the second gap d2. In other words, two adjacent patterns of the second active region ACT_2 may not be in contact with each other in the second direction DR2.

In some example embodiments, the second width W2 may be greater than the first width W1. In other words, the curved pattern of the second active region ACT_2 may protrude from the first active region ACT_1 having a bar shape, and accordingly, the active region ACT may have a shape having a combination of a straight line and a curve when the entire cross-sectional view of the active region ACT is observed.

In some example embodiments, the third width W3 may not be greater than the third gap d3. During a trimming process, an insulating pattern TL may be formed to have the third width W3 such that the curved portion of each pattern of the second active region ACT_2 is at least partially left.

A distance (referred to as a first distance f1) between two adjacent patterns of the first active region ACT_1 in the first direction DR1 may be proportional to an interval (referred to as a second distance f2) between adjacent patterns of the second active region ACT_2 along one insulating pattern TL. For example, the first distance f1 and the second distance f2 may be formed at a ratio of 3 to 2.6. For example, the first distance f1 may correspond to three times the gap between adjacent pitches and the second distance f2 may correspond to 2.6 times the gap between adjacent pitches. However, the values of the first distance f1 and the second distance f2 are not limited by the example ratio mentioned above.

According to some example embodiments, a semiconductor memory device may include a structure, in which an asymmetric pattern of an active region is repeated, by forming a pattern of the active region having a combination of a straight line and a curve by using a line pattern and a hole pattern and forming an insulating pattern by performing a trimming process in a diagonal direction. Due to asymmetric patterns, the area of the active region may increase, and accordingly, a contact area may be increasingly or more likely to be secured. Alternatively or additionally, because the mechanical stability increases due to an asymmetrical structure, the warpage of the active region may be improved.

While inventive concepts have been particularly shown and described with reference to embodiments thereof, it will be understood that various changes in form and details may be made therein without departing from the spirit and scope of the following claims. Additionally example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a substrate having a memory cell region and a dummy cell region surrounding the memory cell region, wherein a plurality of memory cells are arranged in the memory cell region;
a plurality of first active regions each having a bar shape in the memory cell region, the plurality of first active regions separated from each other by a first gap in a first direction and extending in a second direction perpendicular to the first direction; and
a plurality of second active regions on the plurality of first active regions, the plurality of second active regions each having a circular shape and separated from each other by a second gap in the second direction.

2. The semiconductor memory device of claim 1, wherein a diameter of the circular shape is less than a width of the second gap.

3. The semiconductor memory device of claim 1, wherein a diameter of the circular shape is greater than a width of each of the plurality of first active regions.

4. The semiconductor memory device of claim 1, wherein a width of the first gap is greater than a width of each of the plurality of first active regions.

5. The semiconductor memory device of claim 1, wherein a top surface of the plurality of second active regions is coplanar with a top surface of the plurality of first active regions.

6. The semiconductor memory device of claim 1, further comprising:
a plurality of insulating patterns on the memory cell region, the plurality of insulating patterns separated from each other by a third gap in an arbitrary direction and dividing the plurality of second active regions,
wherein the arbitrary direction has an acute angle with respect to the first direction and the second direction on the substrate.

7. The semiconductor memory device of claim 6, wherein each of the plurality of insulating patterns passes through a center of the circular shape.

8. The semiconductor memory device of claim 6, wherein a width of each of the plurality of insulating patterns is not greater than a width of the third gap.

9. A semiconductor memory device comprising:
a substrate having a memory cell region and a dummy cell region surrounding the memory cell region, wherein a plurality of memory cells are arranged in the memory cell region;
a plurality of first active regions each having a bar shape in the memory cell region, the plurality of first active regions separated from each other by a first gap in a first direction and extending in a second direction perpendicular to the first direction; and
a plurality of second active regions on the plurality of first active regions, the plurality of second active regions each including a curve and separated from each other by a second gap in the second direction.

10. The semiconductor memory device of claim 9, wherein each of the plurality of second active regions has an oval shape.

11. The semiconductor memory device of claim 10, wherein
a long axis of the oval shape is parallel with the first direction, and
a length of the long axis of the oval shape is greater than a width of each of the plurality of first active regions and less than the second gap.

12. The semiconductor memory device of claim 9, wherein a width of the first gap is greater than a width of each of the plurality of first active regions.

13. The semiconductor memory device of claim 9, wherein, when
a greatest width of a shape of each of the plurality of second active regions is defined as a width of each of the plurality of second active regions,
the width of each of the plurality of second active regions is greater than a width of each of the plurality of first active regions.

14. The semiconductor memory device of claim 9, wherein a top surface of the plurality of second active regions is coplanar with a top surface of the plurality of first active regions.

15. The semiconductor memory device of claim 9, further comprising:
a plurality of insulating patterns on the memory cell region, the plurality of insulating patterns separated from each other by a third gap in an arbitrary direction and dividing the plurality of second active regions,
wherein the arbitrary direction has an acute angle with respect to the first direction and the second direction on the substrate.

16. The semiconductor memory device of claim 15, wherein a width of each of the plurality of insulating patterns is not greater than a width of the third gap.

17. A semiconductor memory device comprising:
a substrate having a memory cell region, a peripheral region, and a dummy cell region between the memory cell region and the peripheral region;
a plurality of first active regions each having a bar shape in the memory cell region, the plurality of first active regions separated from each other by a first gap in a first direction and extending in a second direction perpendicular to the first direction;
a plurality of second active regions on the plurality of first active regions, the plurality of second active regions each including a curve and separated from each other by a second gap in the second direction;
at least one logic active region in the peripheral region;
a plurality of dummy active regions in the dummy cell region;
an isolation structure defining the plurality of first active regions, the plurality of second active regions, the at least one logic active region, and the plurality of dummy active regions;
a plurality of word lines extending across the plurality of first active regions, the plurality of second active regions, and the plurality of dummy active regions in the first direction and being parallel with each other;
a plurality of bit lines extending in the second direction on the substrate and being parallel with each other;
a plurality of buried contacts on the substrate and filling a lower portion of a space between the plurality of bit lines;
a plurality of landing pads filling an upper portion of the space between the plurality of bit lines and extending on the plurality of bit lines; and
a plurality of memory structures respectively connected to the plurality of landing pads.

18. The semiconductor memory device of claim 17, wherein each of the plurality of second active regions has a circular shape or an oval shape.

19. The semiconductor memory device of claim 18, further comprising:
a plurality of insulating patterns on the memory cell region, the plurality of insulating patterns separated from each other by a third gap in an arbitrary direction and dividing the plurality of second active regions,
wherein the arbitrary direction forms an acute angle with respect to the first direction and the second direction on the substrate.

20. The semiconductor memory device of claim 19, wherein a width of each of the plurality of insulating patterns is not greater than a width of the third gap.
